(19) United States
(12) Patent Application Publication
(10) Pub. No.: US 2023/0081862 A1
(43) Pub. Date: Mar. 16, 2023

(54) Focus Ring Regeneration

(71) Applicant: Tokyo Electron Limited, Minato-ku (JP)

(72) Inventors: Yanxiang Shi, Albany, NY (US); Yu-Hao Tsai, Albany, NY (US); Katie Lutker-Lee, Albany, NY (US); Angelique Raley, Albany, NY (US); Mingmei Wang, Albany, NY (US)

(21) Appl. No.: 17/471,971

(22) Filed: Sep. 10, 2021

(51) Int. Cl. H01J 37/32; H01L 21/3065; H01L 21/66

(52) U.S. Cl. CPC H01J 37/3288; H01J 37/32642; H01J 37/32449; H01L 21/3065; H01L 22/26; H01J 2237/332; H01J 2237/334

(57) ABSTRACT

A method for plasma processing that includes: loading a dummy wafer between a focus ring positioned within a plasma process chamber; depositing a material layer over the focus ring by a plasma deposition process within the plasma process chamber; removing the dummy wafer from the plasma process chamber, and loading a substrate to be processed between the focus ring with the material layer within the plasma process chamber and performing a plasma process on the substrate.

### TECHNICAL FIELD

The present invention relates generally to focus rings, and, in particular embodiments, to focus ring regeneration, for example, used in plasma equipment.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes. Plasma processing techniques need to provide a uniform distribution of plasma across a wafer so that a high die yield with process consistency may be obtained.

Obtaining and maintaining the uniform distribution of plasma, particularly at wafer edges, may be challenging due to non-uniformity of various factors such as gas flow distribution, electrode temperature distribution, and electrical and magnetic field distribution. To mitigate this non-uniformity issue, a focus ring may be used for better uniformity of plasma distribution. However, the focus ring may be degraded and consumed over cycles of operation.

### SUMMARY

In accordance with an embodiment of the present invention, a method for plasma processing that includes: loading a dummy wafer between a focus ring positioned within a plasma process chamber; depositing a material layer over the focus ring by a plasma deposition process within the plasma process chamber; removing the dummy wafer from the plasma process chamber, and loading a substrate to be processed between the focus ring with the material layer within the plasma process chamber and performing a plasma process on the substrate.

In accordance with an embodiment of the present invention, a method of processing a plurality of substrates that includes: repeating a plurality of fabrication steps, each of the fabrication steps including plasma processing the plurality of substrates held within a focus ring inside a plasma process chamber, the plasma processing etching the focus ring, and performing, in the plasma process chamber, a focus ring regeneration process to deposit a material layer over the etched focus ring.

In accordance with an embodiment of the present invention, a method for processing a substrate that includes: performing a plasma etch process on a substrate disposed in a plasma process chamber, the substrate being positioned between a focus ring within the plasma process chamber, the focus ring including a first metal; after the plasma etch process, replacing the substrate with a dummy wafer; performing, on the dummy wafer, a focus ring regeneration process in the plasma process chamber by depositing a material layer including a second metal over the focus ring; and replacing the dummy wafer with a new substrate to be processed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate a substrate and a focus ring in accordance with an embodiment, wherein FIG. 1A illustrates a top view, and FIG. 1B illustrates a cross-sectional view;

FIG. 2A-2F illustrate cross-sectional views of a substrate and a focus ring at various intermediate stages in a plasma etch process comprising a focus ring regeneration process in accordance with various embodiments, wherein FIG. 2A illustrates at the start of the plasma etch process, FIG. 2B illustrates after repeating the plasma etch process, FIG. 2C illustrates at the start of focus ring regeneration after loading a dummy wafer in a plasma process chamber, FIG. 2D illustrate after focus ring regeneration, FIG. 2E illustrates after loading a next substrate to be processed next in the plasma etch process in the plasma process chamber, and FIG. 2F illustrates the next substrate during the plasma etch process using the regenerated focus ring;

FIGS. 3A-3D illustrate flow diagrams of a plasma process comprising a focus ring regeneration process in accordance with various embodiments, wherein FIG. 3A illustrates an embodiment, FIG. 3B illustrates an alternate embodiment, FIG. 3C illustrates a different embodiment, and FIG. 3D illustrates yet another embodiment where a deposition gas comprises a metal;

FIG. 4 illustrates a cross-sectional view of an example plasma system for performing a plasma etch process comprising a focus ring regeneration process in accordance with various embodiments.

### DETAILED DESCRIPTION OF ILLUSTRATIVE EMBODIMENTS

This application relates to a method of processing a substrate during semiconductor device fabrication, more particularly to a method of in-line focus ring regeneration by depositing a material layer on a consumed focus ring. In a typical plasma process for a substrate, a focus ring may be used to maintain and extend the uniformity of plasma to achieve process consistency at the edge of the substrate. However, the focus ring may be degraded and consumed over a prolonged usage from repeating plasma processes, leading to the loss of plasma uniformity at the edge and thereby reduced die yield. To replace an old focus ring with a new focus ring, time-consuming open chamber service with equipment downtime is generally necessary. Therefore, a method of maintaining and/or regenerating a focus ring without significant equipment downtime may be desired. Embodiments of the present application disclose a method of in-line focus ring regeneration based on a plasma deposition process, for example, using a silicon halide.

The method described in this disclosure may extend the lifetime of focus ring without opening the chamber, thereby advantageously reducing the frequency of open chamber service required for replacing a consumed focus ring. The in-line focus ring regeneration in accordance with various embodiments may be flexibly integrated at any stage between steps of a plasma process (e.g., reactive ion etching). The timing and frequency of the in-line focus ring regeneration may be determined based on the rate of focus ring consumption. Accordingly, the method in this disclosure enables easier and faster focus ring maintenance/regeneration, and may improve the die yield especially at the edge of substrate and the efficiency of plasma processing for semiconductor device fabrication.

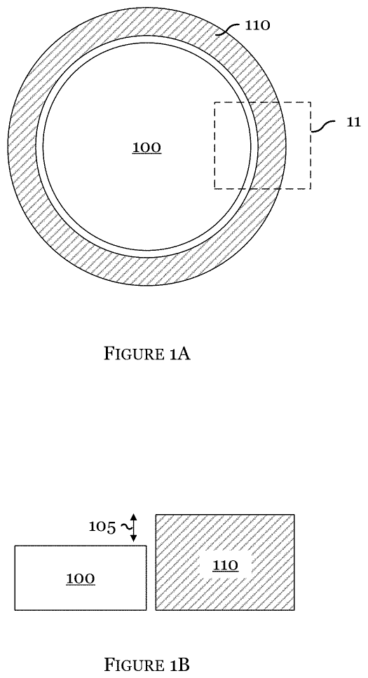

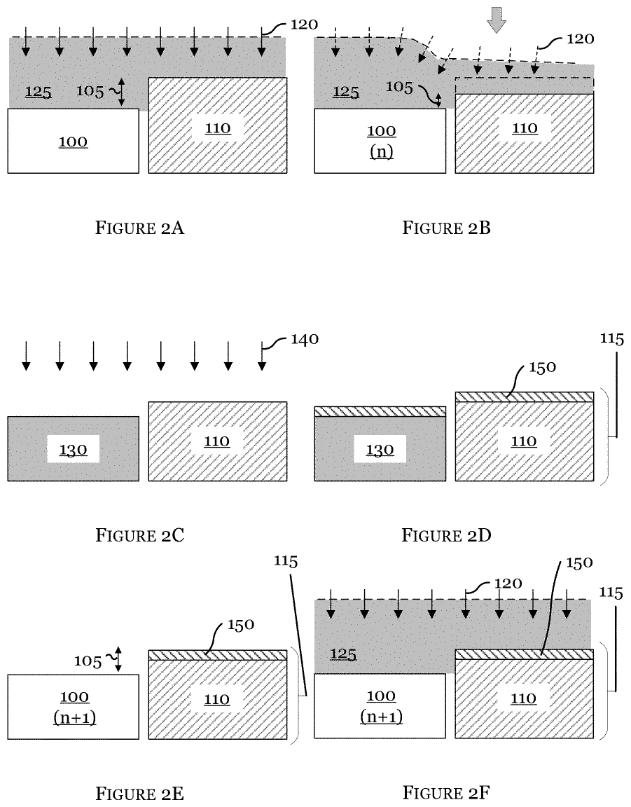

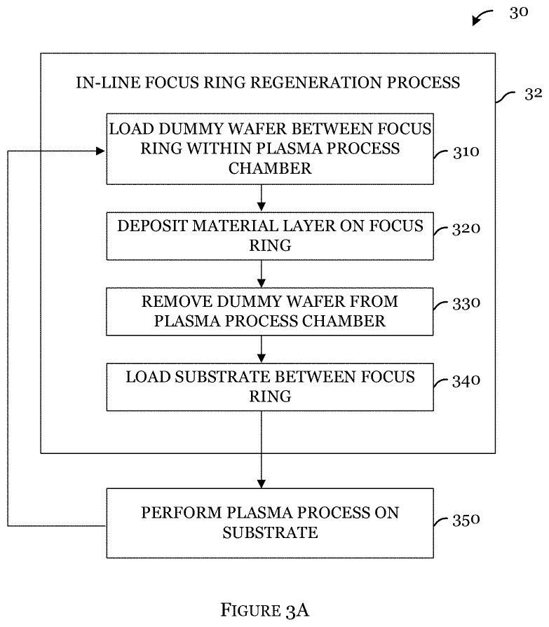

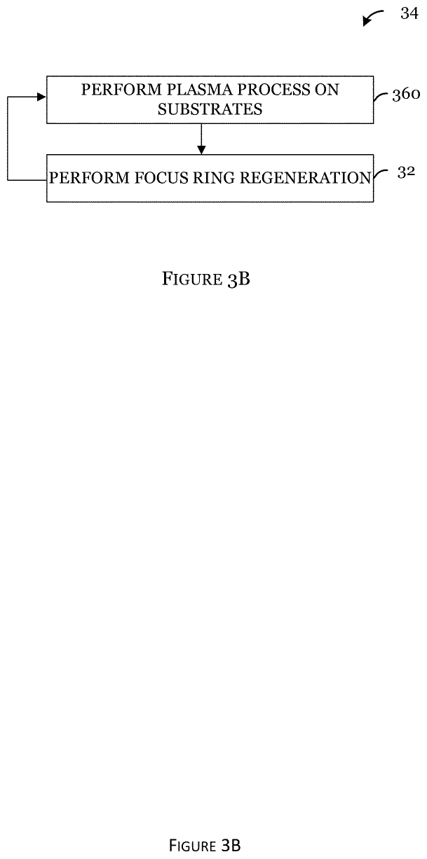

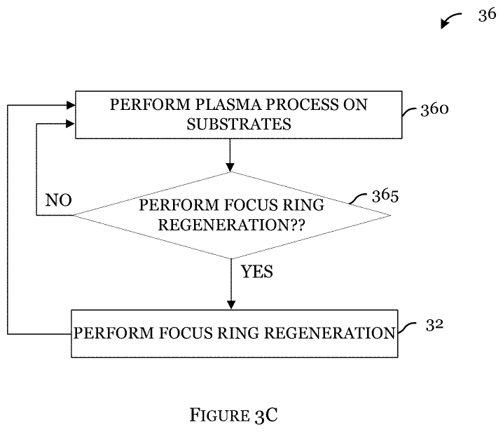

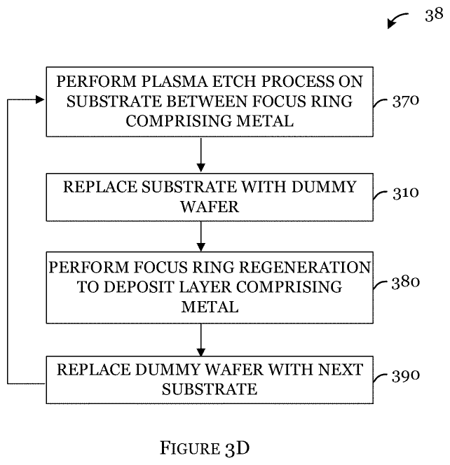

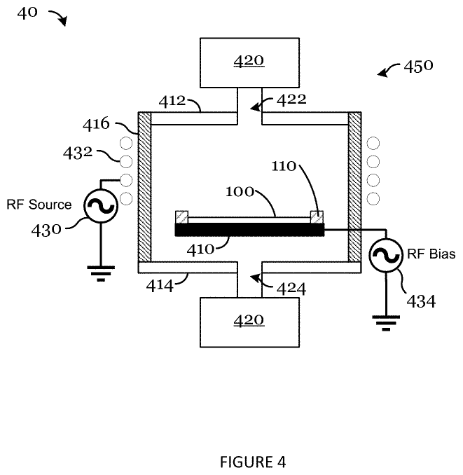

In the following, an example configuration of a substrate and a focus ring is first described referring to FIGS. 1A and 1B. The method of in-line focus ring regeneration is then illustrated in FIGS. 2A-2F with cross-sectional views in accordance with various embodiments. The process flow diagrams are illustrated in FIGS. 3A-3D, and an example plasma system is illustrated in FIG. 4.

In all figures in the disclosure, the drawn features are not to scale and for illustration purposes only.

FIGS. 1A and 1B illustrate a substrate 100 and a focus ring no in accordance with an embodiment, wherein FIG. 1A illustrates a top view, and FIG. 1B illustrates a cross-sectional view.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device. In various embodiments, the substrate 100 has a disk shape. In one or more embodiments, the diameter of the substrate 100 may be 200 mm or 300 mm. Typically, the substrate 100 may be cut into dice at a later stage after various semiconductor fabrication processes, and dice that do not meet the specification requirements are discarded or binned differently. Therefore, it is important to achieve and maintain the uniformity of plasma and other process conditions across the entire region of the substrate 100 to maximize the die yield.

A focus ring may be used to improve the uniformity of plasma across the substrate 100. As illustrated in FIG. 1A, the focus ring no may be a ring that surrounds the substrate 100. In various embodiments, the focus ring no may have a width of a few cm. In various embodiments, there may be a gap for mechanical clearance between the circumference of the substrate 100 and the focus ring 110. In certain embodiments, the gap may be hundreds of microns to a few mm. In various embodiments, the focus ring no may comprise a dielectric material with a desired dielectric constant. In certain embodiments, the focus ring no may comprise silicon. Some examples of silicon-based focus ring may comprise silicon, silicon oxide, doped silicon (e.g., boron-doped, nitrogen-doped, and phosphorous-doped), or silicon carbide. Alternatively, in some embodiments, the focus ring may comprise a carbon-based material. The focus ring no may be metal-free in some embodiments, especially for a system where a metal contamination is strictly prohibited. In other embodiments, the focus ring no may comprise a metal. In certain embodiments, the metal may comprise aluminum or zirconium. Specifically, a metal oxide with a desired dielectric constant may be used for the focus ring 110. In one or more embodiments, the focus ring may comprise aluminum oxide or zirconium oxide. The desired dielectric constant may be determined based on the dielectric constant of the substrate 100 and other factors of the plasma system to achieve the uniformity of plasma (e.g., a plasma sheath thickness) across the substrate 100.

In FIG. 1B, a cross-sectional view of the substrate 100 and the focus ring no is illustrated corresponding to a section 11 in FIG. 1A.

In various embodiments, the focus ring no may be a flat ring, represented by a rectangle in the cross-sectional view as illustrated. In alternate embodiments, the focus ring no may comprise a groove or any other features. In one embodiment, the focus ring no may comprise a step and two flat surfaces with different levels. As illustrated in FIG. 1B, in various embodiments, a newly installed focus ring may be positioned so that the top surface is higher than the top surface of a substrate. For example, the substrate 100 and the focus ring no are positioned with a height difference 105. In certain embodiments, as illustrated in FIG. 1B, the substrate 100 and the focus ring no may be positioned on a same level of a pedestal, where the height difference 105 is equal to the difference in thickness. In alternate embodiments, the substrate 100 and the focus ring no may be positioned on a different level. In various embodiments, the initial thickness of the focus ring no may be optimized to provide a desired initial value of the height difference 105 so that the uniformity of plasma may be obtained across the substrate 100. In certain embodiments, for providing the optimized uniformity of plasma, the height difference 105 may initially be a few hundreds of microns. In this disclosure, the height difference 105 is referenced to the level of the substrate 100, and thereby a positive value for the height difference 105 indicates a position of the top surface of the focus ring no higher than that of the substrate 100.

FIGS. 2A-2F illustrate cross-sectional views of a substrate 100 and a focus ring no at various intermediate stages in a plasma etch process comprising a focus ring regeneration process in accordance with various embodiments.

FIG. 2A illustrates a partial cross-sectional view inside the plasma process chamber at the start of the plasma etch process.

In various embodiments, the plasma etch process may comprise one or more anisotropic reactive ion etch (RIE) processes. Any common etch gas such as carbon tetrafluoride (CF₄), dioxygen (O₂), or other gases may be used for etching in accordance with various embodiments. A plasma for etching 120 is illustrated in FIG. 2A. The presence of the focus ring no with a height difference 105 allows the uniformity of the plasma for etching 120, as also illustrated by a plasma sheath 125 having a uniform thickness across the substrate 100. With the maintained uniformity of the plasma for etching 120, the reactive ions have a uniform directionality (e.g., perpendicular to the surface of the substrate 100, as illustrated as parallel arrows of the plasma for etching 120 in FIG. 2A) across the substrate 100 including the edge regions.

FIG. 2B illustrates a partial cross-sectional view inside the plasma process chamber after repeating the plasma etch process.

In various embodiments, the plasma etch process may be repeated to process a plurality of substrates, and each of the plasma etch process may process one substrate. For example, in an example embodiment illustrated in FIG. 2B, after n times of the plasma etch process, n substrates have been processed, where n is an integer greater than 1. The last substrate processed (n th substrate) is referred to as a substrate 100(n). The focus ring no may be consumed over these repeated processes because of accumulated exposure to the reactive ions of the plasma for etching 120. Consequently, the height difference 105 may be reduced as illustrated. In certain embodiments, the focus ring 110 may be consumed unevenly due to non-uniformity of the plasma etch process and may have a tilted surface. The rate of focus ring consumption may depend on the dose of the reactive ions. As described above, thinning of the focus ring no may lead to degrade the uniformity of the plasma for etching 120. More specifically, when the focus ring no is consumed and becomes thinner, the plasma sheath 125 formed above the focus ring no (i.e., the peripheral portion of the substrate 100) becomes lower than the position of the plasma sheath formed above the central portion of the substrate 100. This lowering of the plasma sheath 125 on the focus ring no leads to a bending of the plasma sheath 125. As a result, a so-called ion edge tilting may occur, where the incident angle of the reactive ions impinging the surface of a substrate is not uniform across the substrate. For example, as illustrated in FIG. 2B, the incident angles of the reactive ions may be different between near the center and the edge of the substrate 100 (e.g., perpendicular to the surface of the substrate 100 vs tilted, respectively). The ion edge tilting caused by the thinning of the focus ring may lead to the loss of process consistency and lowering the die yield of fabrication at the edge of the substrate. Conventionally, when the consumed focus ring no is no longer capable of maintaining an acceptable uniformity of plasma, the equipment needs open chamber service with equipment downtime to install a new focus ring and eliminate the ion edge tilting. The method of in-line focus ring regeneration in accordance with various embodiments may overcome this issue by depositing a solid layer comprising a material same as or similar to the focus ring on the consumed focus ring. With the method, it is possible to correct or avoid the ion edge tilting before it severely impacts the process consistency.

The in-line focus ring regeneration may be integrated as a part of the plasma process for treating a plurality of substrates and performed at any stages between steps of the plasma process. In various embodiments, the timing and frequency of the in-line focus ring regeneration may be predetermined based on a number of substrates to be processed before the in-line focus ring regeneration. In one embodiment, for example, the in-line focus ring regeneration may be performed for every 10 substrates processed (i.e., n=10 in FIG. 2B). In alternate embodiments, the rate of focus ring consumption may be monitored during the plasma process and a real-time decision to perform in-line focus ring regeneration may be made based on the collected data. In these embodiments, the frequency of performing in-line focus ring regeneration may advantageously be optimized. Any method of monitoring (e.g., optical measurement of focus ring thickness using a camera) may be integrated with the method of this disclosure. Further, the timing of in-line focus ring regeneration may also be determined considering possible coupling with other necessary steps such as system maintenance between steps of the plasma etch process. For example, dry cleaning processes of the plasma process chamber may be performed in tandem with in-line focus ring regeneration. In one embodiment, only one in-line focus ring regeneration may be performed every couple of maintenance process steps, instead of before or after every maintenance process step. In the following, referring to FIGS. 2C-2E, steps of in-line focus ring regeneration are described.

FIG. 2C illustrates a partial cross-sectional view inside the plasma process chamber at the start of focus ring regeneration process after loading a dummy wafer 130 in the plasma process chamber.

Before performing a deposition for focus ring regeneration, the dummy wafer 130 may be loaded in the plasma process chamber. The dummy wafer 130 is used to protect the pedestal from any deposition and not to contaminate any subsequent real substrate for processing. The dummy wafer 130 may comprise a material same as or similar to the substrate wo. After loading the dummy wafer 130 in the plasma process chamber, a plasma for deposition 140 may be generated from a deposition gas. The in-line focus ring regeneration may be performed by exposing the focus ring no to the plasma for deposition 140 to form a material layer.

In certain embodiments, the monitoring method mentioned above or the like may also be used to monitor the progress of in-line focus ring regeneration by quantifying the thickness of the material layer. This data may be used to determine the end point of the regeneration process.

FIG. 2D illustrates a cross-sectional view inside the plasma process chamber after the focus ring regeneration process.

As illustrated, a material layer 150 is formed over the focus ring no after exposing the focus ring no to the plasma for deposition 140 of FIG. 2C. In various embodiments, the material layer 150 may also be formed over the dummy wafer 130. The deposition gas composition may be selected according to a target material for the material layer 150.

In various embodiments, the deposition gas may comprises silicon in order to form the material layer 150 comprising silicon. In certain embodiments, the deposition gas may comprise a silicon halide. Examples of the silicon halide include silicon tetrachloride (SiCl₄), silicon tetrafluoride (SiF₄) and silicon tetrabromide (SiBr₄). In some embodiments, the deposition gas may comprises a hydrohalosilane. The hydrohalosilane may comprise a silane with a general formula SiFₓCl_{y}H_{z} (x+y+z=4) or Si₂FₓCl_{y}H_{z} (x+y+z=6). For example, the hydrohalosilane may be SiCl₃H, SiFCl₂H, or Si₂F₂Cl₂H₂. In one or more embodiments, the deposition gas may comprise an amino silane. Examples of the amino silane include (trimethylsilyl)dimethylamine (TSDMA).

The composition of the deposition gas may be selected according to a target composition of the material layer 150 desired for the material used for the focus ring no. For example, in certain embodiments, when the focus ring no comprises a carbon-based material, the deposition gas may comprise carbon such as fluorocarbon.

Although not wishing to be limited by any theory, the formation of the material layer 150 comprising silicon in some embodiments may proceed with following four steps: (1) adsorption of silicon species (e.g., a silicon halide) on the surface of the focus ring; (2) silicon activation; (3) silicon crosslinking to form Si—Si bonding; and (4) halogen removal.

In various embodiments, the deposition gas may comprise a silicon-containing compound and dihydrogen (H₂). In these embodiments, H₂ may generate dissociated hydrogen radicals on the surface of a focus ring and facilitate the silicon activation step. Addition of H₂, however, may be optional, and if the silicon-containing compound also comprises hydrogen, the silicon-containing compound may also serve as a precursor for hydrogen radicals even with the absence of H₂ in the deposition gas.

In various embodiments, a carrier gas may also be introduced to the plasma process chamber during the in-line focus ring regeneration process. Examples of the carrier gas include helium (He) and argon (Ar). Although not wishing to be limited by any theory, energized ions of carrier gas components may be beneficial in selectively sputtering and removing by-products such as those comprising halogens (i.e., the halogen removal step). Accordingly, process parameters such as source and bias powers for plasma and a gas flow rate of the carrier gas may be selected to achieve an optimized rate of deposition with a desired chemical composition. Further, sputtering by the energized ions of carrier gas components may also induce a change in the morphology of the material layer 150. In one embodiment, the material layer 150 may primarily be a porous silicon and be converted to a dense silicon by the ion bombardment.

In various embodiments, an additive gas may also be introduced to the plasma process chamber during the in-line focus ring regeneration to enable various options for the chemical composition of the material layer 150. Examples of the additive gas include dioxygen (O₂), dinitrogen (N₂), ozone (O₃), boron halide, boron hydride, phosphorus halide, and phosphorus hydride. Examples of boron and phosphorus compounds include BH₃, B₂H₆, PH₃, and PCl₃. The additive gas may be a gas mixture in certain embodiments. The additive gas may enable the material layer 150 to comprise, for example, silicon oxide or various types of doped silicon (e.g., boron-doped, nitrogen-doped, and phosphorous-doped).

While silicon may be the primary component of the material layer 150 in various exemplary embodiments to match with a common silicon-based focus ring, in one or more embodiments, a metal-containing deposition gas may be used to form the material layer 150 comprising metal with or without silicon. Such embodiments may be beneficial especially for a metal oxide-based focus ring. In certain embodiments, the deposition gas may comprise an organometallic compound. In one or more embodiments, the deposition gas may comprise trimethylaluminum (TMA) to form a material layer 150 comprising aluminum oxide (Al₂O₃). In alternate embodiments, the deposition gas may comprise tetrakis(ethylmethylamido)zirconium (TEMAZ) to form a material layer 150 comprising zirconium oxide (ZrO₂). Other metal oxides or the like may also be a target material for the material layer 150 and appropriate precursors may be selected to be included in the deposition gas. In these embodiments where the deposition gas comprises a metal, similar to the prior embodiments, a carrier gas and/or an additive gas may also be introduced to the plasma process chamber to tune the composition of the material layer 150. In one embodiment, an additive gas comprising dioxygen (O₂) may be flowed to the plasma process chamber to form the material layer 150 comprising a metal oxide.

Process parameters for the in-line focus ring regeneration may comprise gas composition for the deposition gas, carrier gas, and additive gas, and its mixture ratio, gas flow rates, pressure, temperature, source power, bias power, and process time among others. In certain embodiments, the process parameters may be selected to control the anisotropy (or conformity) of the deposition of the material layer 150. For example, a conformal deposition may be particularly useful when the focus ring no has a feature such as a groove. Further, in one embodiment, particularly adjusting the gas flow rate of H₂, the gas flow rate of the carrier gas (e.g., Ar), the source power for the plasma, or a combination of any of these parameters may change the anisotropy of the deposition. Fine adjustment of process parameters enables correcting a possible tilted surface of the consumed focus ring to a flat surface, or creating a tilted surface. Such an adjustment may be performed during the deposition process continuously or stepwise. Additionally, local gas flow control may also be possible using zoned gas injection in the edge region of the wafer near the focus ring. Furthermore, individually controlling the bias applied to the focus ring or regions of the dummy wafer in the proximity may also be useful to fine tune the anisotropy (or conformity) of the deposition.

Further, in various embodiments, the process parameters may be selected to optimize the chemical composition of the material layer 150 and its deposition rate to achieve a desirable thickness. The resulting thickness of the material layer 150 is an important factor that determines a successful focus ring regeneration. In one one embodiment, a regenerated focus ring 115 (a stacked layer of the focus ring no and the material layer 150) may have a thickness equal to that of the focus ring no at the initial stage (e.g., FIG. 2A). In other embodiments, the height of the thickness of the regenerated focus ring 115 may be less than that of the focus ring no at the initial stage. The in-line focus ring regeneration process may be targeted at achieving the regenerated focus ring 115 having a dielectric constant equal or close to the focus ring no at the initial stage (e.g., FIG. 2A). In certain embodiments, the material layer 150 may have a chemical composition different from the focus ring no. In such embodiments, if the material layer 150 has a dielectric constant higher than the focus ring no, the thickness of the regenerated focus ring 115 may be less than that of the focus ring no at the initial stage while achieving the overall dielectric constant of the regenerated focus ring 115 equal to the focus ring no at the initial stage. The process time for one in-line focus ring regeneration process and the frequency of performing in-line focus ring regeneration processes may be a trade-off and selected in consideration of overall process efficiency. In one embodiment, a high frequency (i.e., selecting a small value for n) may be selected so that only a short process time for regeneration of the focus ring no may be necessary each time. On the other hand, a low frequency (i.e., selecting a large value for n) may be selected, advantageously reducing the number of in-line focus ring regeneration processes for a given number of the repeated plasma processes, although a process time may need to be longer each time. In various embodiments, the thickness of the material layer 150 may be between 5% and 30% of the thickness of an initial focus ring. In certain embodiments, the thickness of the material layer 150 may be between 5 nm and moo nm.

In certain embodiments, after exposing the focus ring 110 to the plasma for deposition 140 (e.g., FIG. 2C-2D), an optional post treatment may be performed to tune the chemical and/or physical properties of the material layer 150. The optional post treatment may comprise a thermal treatment (e.g., an annealing process in vacuum or in an inert gas), a plasma treatment, or other processes. In one or more embodiments, the post treatment may comprise exposing the material layer 150 to a plasma of argon (Ar), dioxygen (O₂), dinitrogen (N₂), or ozone (O₃).

FIG. 2E illustrates a cross-sectional view inside the plasma process chamber after loading a next substrate 100(n+1) to be processed next in the plasma etch process in a plasma process chamber.

In FIG. 2E, the dummy wafer 130 is replaced with the next substrate 100(n+1) to be processed next in the plasma etch process. The height difference 105 may be equal to that at the initial stage (e.g., FIG. 2A) or smaller, but greater than that at the consumed stage (e.g., FIG. 2B). With the regenerated focus ring 115 and the next substrate 100(n+1) loaded in the plasma process chamber, it is ready for a next plasma etch process and provide the uniformity of plasma.

FIG. 2F illustrates a next substrate during a next plasma etch process with the regenerated focus ring 115.

In FIG. 2F, the next plasma etch process may be performed using the regenerated focus ring 115. Since the regenerated focus ring 115 offers the uniformity of the plasma sheath 125 and the plasma for etching 120, the reactive ions have a uniform directionality (e.g., perpendicular to the surface of the substrate 100(n+1), as illustrated as parallel arrows of the plasma for etching 120 in FIG. 2F) across the substrate 100 including the edge regions. Therefore, the issue of ion edge tilting may advantageously be minimized or eliminated by the embodiment method without requiring open chamber service. Accordingly, in certain embodiments, the plasma process chamber may be advantageously maintained at low pressure continuously during the intervening times between the performing of the plasma etch process, the replacing of the substrate, the focus ring regeneration process, and the replacing the dummy wafer. In various embodiments, a plasma etch process may continue repeating the same procedures described above (e.g., FIGS. 2A-2F), with repeating in-line focus ring regeneration until it fails to provide the uniformity of plasma and requires a new focus ring to be installed, when open chamber service may be performed.

FIGS. 3A-3D illustrate flow diagrams of a plasma process comprising a focus ring regeneration process in accordance with various embodiments. Example process flows follow in accordance with the embodiments already described above referring to FIGS. 2A-2E, and therefore the details will not be repeated.

In FIG. 3A, in accordance with an embodiment, a plasma process 30 comprises an in-line focus ring regeneration process 32, which starts with loading a dummy wafer (e.g., the dummy wafer 130 in FIG. 2C) between a focus ring within a plasma process chamber (block 310). Next, in block 320, the focus ring is exposed to the plasma of a deposition gas to form a material layer (block 320, e.g., FIGS. 2C and 2D). In various embodiments, the focus ring regeneration may be performed by flowing a deposition gas to the plasmas process chamber, generating a plasma from the deposition gas by applying a source power and a bias power to electrodes of the plasma process chamber, and exposing the focus ring to the plasma for deposition. After the deposition, a next substrate (e.g., the substrate 100(n+1) in FIG. 2E) is loaded in the plasma process chamber to replace the dummy wafer (block 340). After the in-line focus ring regeneration process, a plasma process may be performed on the next substrate (block 350, e.g., FIG. 2F). The plasma process may continue to process a plurality of substrates, and when the focus ring is consumed, another in-line focus ring regeneration process may be performed.

In FIG. 3B, in accordance with an alternate embodiment, a plasma process 34 starts with performing a plasma process on a plurality of substrates (block 360, e.g., FIGS. 2A-2B) in a plasma process chamber. During the plasma process on the plurality of substrates, a focus ring may be etched, gradually losing its ability to maintain the uniformity of plasma across the substrate. After processing the plurality of substrates, an in-line focus ring regeneration process 32 may be performed by depositing a material layer over the etched focus ring. Steps of the in-line focus ring regeneration 32 may be same as the prior embodiment illustrated in FIG. 3A.

FIG. 3C illustrates an alternate embodiment that comprises making a decision when to perform in-line focus ring regeneration. In FIG. 3C, a plasma process 36 starts with performing a plasma process on a plurality of substrates (block 360, e.g., FIGS. 2A-2B) in a plasma process chamber. The plasma process may comprise steps of loading a substrate (e.g., the substrate 100 in FIG. 2A) in a plasma process chamber, flowing an etch gas to the plasma process chamber, generating a plasma from the etch gas by applying a source power and a bias power to electrodes of the plasma process chamber, and etching the substrate by exposing it to the plasma of the etch gas (e.g., FIG. 2A). This series of steps may be repeated to treat the plurality of substrates. After the plasma process, a decision is made whether or not to perform in-line focus ring regeneration before continuing to a next step (block 365). As described above, this decision making process may be based on the result of monitoring the change in thickness of the focus ring. For example, a threshold consumption of focus ring (e.g., 5%) may be predetermined, and the monitoring of the focus ring may be used to determine if the focus ring consumption (i.e., thinning) exceeds the threshold. If the focus ring consumption is greater than the threshold, in-line focus ring regeneration may be performed (YES arrow to proceed to the in-line focus ring regeneration process 32). When the focus ring consumption is still less than the threshold, more substrates may be processed by the plasma process (e.g., etching) without regeneration, for example, starting by loading a next substrate (NO arrow to return to block 360). The in-line focus ring regeneration process may be performed in the same fashion as the prior embodiment illustrated in FIG. 3A. After the in-line focus ring regeneration process 32, the process flow may go back to performing the plasma process (block 360, e.g., FIGS. 2E and 2F).

FIG. 3D illustrates another embodiment, where a deposition gas comprises a metal.

In FIG. 3D, a process flow 38 follows steps similar to the prior embodiment illustrated in FIG. 3A. First, a plasma etch process (block 370, e.g., FIG. 2A) is performed on a substrate positioned between a focus ring comprising a metal in a plasma process chamber, and the plasma etch process may be repeated for a plurality of substrates, which may gradually consume the focus ring. Then, in block 310, a dummy wafer (e.g., the dummy wafer 130 in FIG. 2C) is loaded in the plasma process chamber to replace the last processed substrate (e.g., the substrate 100(n) in FIG. 2B). Next, an in-line focus ring regeneration process is performed (block 380). This step may be performed by flowing a deposition gas comprising the metal into the plasma process chamber, generating a plasma of the deposition gas, and exposing the focus ring to the plasma of the deposition gas to form a metal-containing material layer (block 380, e.g., FIGS. 2C and 2D). After the in-line focus ring regeneration, a next substrate (e.g., the substrate 100(n+1) in FIG. 2E) is loaded in the plasma process chamber to replace the dummy wafer (block 390). The plasma etch process may then continue to etch the next substrate (e.g., FIG. 2F).

FIG. 4 illustrates a cross-sectional view of an example plasma processing system 40 for performing a plasma etch process comprising a focus ring regeneration process in accordance with various embodiments.

The plasma system 40 has a plasma process chamber 450 configured to sustain plasma directly above a substrate 100 loaded onto a substrate holder 410. A focus ring no surrounds the substrate 100. A process gas may be introduced to the plasma process chamber 450 through a gas inlet 422 and may be pumped out of the plasma process chamber 450 through a gas outlet 424. The gas inlet 422 and the gas outlet 424 may comprise a set of multiple gas inlets and gas outlets, respectively. The gas flow rates and chamber pressure may be controlled by a gas flow control system 420 coupled to the gas inlet 422 and the gas outlet 424. The gas flow control system 420 may comprise various components such as high pressure gas canisters, valves (e.g., throttle valves), pressure sensors, gas flow sensors, vacuum pumps, pipes, and electronically programmable controllers. An RF bias power source 434 and an RF source power source 430 may be coupled to respective electrodes of the plasma process chamber 450. The substrate holder 610 may also be the electrode coupled to the RF bias power source 434. The RF source power source 430 is shown coupled to a helical electrode 432 coiled around a dielectric sidewall 416. In FIG. 6, the gas inlet 422 is an opening in a top plate 412 and the gas outlet 424 is an opening in a bottom plate 414. The top plate 412 and bottom plate 414 may be conductive and electrically connected to the system ground (a reference potential).

The configuration of the plasma processing system 40 described above is by example only. In alternative embodiments, various alternative configurations may be used for the plasma processing system 40. For example, inductively coupled plasma (ICP) may be used with RF source power coupled to a planar coil over a top dielectric cover, or capacitively coupled plasma (CCP) generated using a disc-shaped top electrode in the plasma process chamber 450, the gas inlet and/or the gas outlet may be coupled to the sidewall, etc. Pulsed RF power sources and pulsed DC power sources may also be used in some embodiments (as opposed to continuous wave RF power sources). An additional component such as a heat tank configured to heat process gases may also be attached to the plasma processing system 40. In various embodiments, the RF power, chamber pressure, substrate temperature, gas flow rates and other plasma process parameters may be selected in accordance with the respective process recipe. In some embodiments, the plasma processing system 40 may be a resonator such as a helical resonator.

Example embodiments of the invention are summarized here. Other embodiments can also be understood from the entirety of the specification as well as the claims filed herein.

Example 1. A method for plasma processing that includes: loading a dummy wafer between a focus ring positioned within a plasma process chamber; depositing a material layer over the focus ring by a plasma deposition process within the plasma process chamber; removing the dummy wafer from the plasma process chamber, and loading a substrate to be processed between the focus ring with the material layer within the plasma process chamber and performing a plasma process on the substrate.

Example 2. The method of example 1, further including, during the plasma deposition process, flowing a deposition gas including silicon tetrachloride (SiCl₄), silicon tetrafluoride (SiF₄), or fluorocarbon.

Example 3. The method of example 1, further including, during the plasma deposition process, flowing a deposition gas including silicon, halogen, and hydrogen, or an amino silane.

Example 4. The method of one of examples 1 to 3, further including, during the plasma deposition process, flowing a deposition gas including dihydrogen (H₂).

Example 5. The method of one of examples 1 to 4, further including, during the plasma deposition process, flowing an inert carrier gas to enhance sputtering of by-products.

Example 6. The method of one of examples 1 to 5, further including, during the plasma deposition process, flowing an additive gas to tune a composition of the material layer.

Example 7. The method of example 6, where the additive gas includes dioxygen (O₂), dinitrogen (N₂), ozone (O₃), boron halide, boron hydride, phosphorus halide, or phosphorus hydride.

Example 8. The method of one of examples 1 to 7, further including: performing the plasma process on a plurality of substrates after a focus ring regeneration process, where the loading, the depositing, and the removing are part of the focus ring regeneration process, and repeating the focus ring regeneration process.

Example 9. The method of one of examples 1 to 8, where the plasma process chamber is maintained at low pressure continuously during the intervening times between the performing of the plasma process, the replacing of the substrate, the focus ring regeneration process, and the replacing the dummy wafer.

Example 10. The method of one of examples 1 to 9, further including determining the total number of the plurality of substrates based on the focus ring regeneration process.

Example 11. The method of one of examples 1 to 10, further including determining a process condition for the plasma deposition process based on the total number of the plurality of substrates.

Example 12. A method of processing a plurality of substrates that includes: repeating a plurality of fabrication steps, each of the fabrication steps including plasma processing the plurality of substrates held within a focus ring inside a plasma process chamber, the plasma processing etching the focus ring, and performing, in the plasma process chamber, a focus ring regeneration process to deposit a material layer over the etched focus ring.

Example 13. The method of example 12, where the focus ring regeneration process further includes: modifying the material layer after depositing to form a regenerated focus ring.

Example 14. The method of example 13, where the modifying includes exposing the material layer to a plasma formed from a tuning gas, the tuning gas including helium (He), argon (Ar), dioxygen (O₂), dinitrogen (N₂), or ozone (O₃).

Example 15. The method of one of examples 12 to 14, further including determining whether or not to perform the focus ring regeneration process based on information of a number of wafers that have been processed or a measured thickness of the focus ring.

Example 16. The method of one of examples 12 to 15, further including determining the total number of the plurality of wafers based on the focus ring regeneration process.

Example 17. The method of one of examples 12 to 16, further including determining a process condition for the plasma processing based on the total number of the plurality of wafers.

Example 18. A method for processing a substrate that includes: performing a plasma etch process on a substrate disposed in a plasma process chamber, the substrate being positioned between a focus ring within the plasma process chamber, the focus ring including a first metal; after the plasma etch process, replacing the substrate with a dummy wafer;

performing, on the dummy wafer, a focus ring regeneration process in the plasma process chamber by depositing a material layer including a second metal over the focus ring; and

replacing the dummy wafer with a new substrate to be processed.

Example 19. The method of example 18, where the first metal and the second metal are aluminum (Al) or zirconium (Zr).

Example 20. The method of one of examples 18 or 19, where the material layer is deposited from a precursor deposition gas including trimethylaluminum or tetrakis(ethylmethylamido)zirconium.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for plasma processing, the method comprising:
loading a dummy wafer between a focus ring positioned within a plasma process chamber;
depositing a material layer over the focus ring by a plasma deposition process within the plasma process chamber;
removing the dummy wafer from the plasma process chamber, and
loading a substrate to be processed between the focus ring with the material layer within the plasma process chamber and performing a plasma process on the substrate.

2. The method of claim 1, further comprising, during the plasma deposition process, flowing a deposition gas comprising silicon tetrachloride (SiCl₄), silicon tetrafluoride (SiF₄), or fluorocarbon.

3. The method of claim 1, further comprising, during the plasma deposition process, flowing a deposition gas comprising silicon, halogen, and hydrogen, or an amino silane.

4. The method of claim 1, further comprising, during the plasma deposition process, flowing a deposition gas comprising dihydrogen (H₂).

5. The method of claim 1, further comprising, during the plasma deposition process, flowing an inert carrier gas to enhance sputtering of by-products.

6. The method of claim 1, further comprising, during the plasma deposition process, flowing an additive gas to tune a composition of the material layer.

7. The method of claim 6, wherein the additive gas comprises dioxygen (O₂), dinitrogen (N₂), ozone (O₃), boron halide, boron hydride, phosphorus halide, or phosphorus hydride.

8. The method of claim 1, further comprising:
performing the plasma process on a plurality of substrates after a focus ring regeneration process, wherein the loading, the depositing, and the removing are part of the focus ring regeneration process, and
repeating the focus ring regeneration process.

9. The method of claim 1, wherein the plasma process chamber is maintained at low pressure continuously during the intervening times between the performing of the plasma process, the replacing of the substrate, the focus ring regeneration process, and the replacing the dummy wafer.

10. The method of claim 8, further comprising determining the total number of the plurality of substrates based on the focus ring regeneration process.

11. The method of claim 8, further comprising determining a process condition for the plasma deposition process based on the total number of the plurality of substrates.

12. A method of processing a plurality of substrates, the method comprising:
repeating a plurality of fabrication steps, each of the fabrication steps comprising
plasma processing the plurality of substrates held within a focus ring inside a plasma process chamber, the plasma processing etching the focus ring, and
performing, in the plasma process chamber, a focus ring regeneration process to deposit a material layer over the etched focus ring.

13. The method of claim 12, wherein the focus ring regeneration process further comprises:
modifying the material layer after depositing to form a regenerated focus ring.

14. The method of claim 13, wherein the modifying comprises exposing the material layer to a plasma formed from a tuning gas, the tuning gas comprising helium (He), argon (Ar), dioxygen (O₂), dinitrogen (N₂), or ozone (O₃).

15. The method of claim 12, further comprising determining whether or not to perform the focus ring regeneration process based on information of a number of wafers that have been processed or a measured thickness of the focus ring.

16. The method of claim 12, further comprising determining the total number of the plurality of wafers based on the focus ring regeneration process.

17. The method of claim 12, further comprising determining a process condition for the plasma processing based on the total number of the plurality of wafers.

18. A method for processing a substrate, the method comprising:
performing a plasma etch process on a substrate disposed in a plasma process chamber, the substrate being positioned between a focus ring within the plasma process chamber, the focus ring comprising a first metal;
after the plasma etch process, replacing the substrate with a dummy wafer;
performing, on the dummy wafer, a focus ring regeneration process in the plasma process chamber by depositing a material layer comprising a second metal over the focus ring; and
replacing the dummy wafer with a new substrate to be processed.

19. The method of claim 18, wherein the first metal and the second metal are aluminum (Al) or zirconium (Zr).

20. The method of claim 19, wherein the material layer is deposited from a precursor deposition gas comprising trimethylaluminum or tetrakis(ethylmethylamido)zirconium.
